(19) United States
(12) Patent Application Publication
(10) Pub. No.: US 2022/0157865 A1
(43) Pub. Date: May 19, 2022

(54) SEMICONDUCTOR APPARATUS, IMAGING APPARATUS, AND METHOD OF PRODUCING A SEMICONDUCTOR APPARATUS

(71) Applicant: SONY SEMICONDUCTOR SOLUTIONS CORPORATION, KANAGAWA (JP)

(72) Inventors: YUJI NISHIDA, KANAGAWA (JP); KIYOHISA SAKAI, KANAGAWA (JP)

(21) Appl. No.: 17/310,935

(22) PCT Filed: Feb. 10, 2020
(86) PCT No.: PCT/JP2020/005021

§ 371 Date: Aug. 31, 2021

(30) Foreign Application Priority Data
Mar. 13, 2019 (JP) 2019-045488
Jul. 9, 2019 (JP) 2019-127399

(51) Int. Cl. H01L 27/146

(52) U.S. Cl. CPC H01L 27/14603; H01L 27/14685; H01L 27/1462

(57) ABSTRACT

To reduce the height of a semiconductor apparatus formed by stacking semiconductor chips. The semiconductor apparatus includes: a first package; a second package; and a connection part. The first package includes a substrate on which a first semiconductor chip and a first wiring connected to the first semiconductor chip are disposed. The second package includes a second semiconductor chip that exchanges a signal with the first semiconductor chip and has a surface on which a pad for transmitting the signal is formed, a sealing part that covers the second semiconductor chip while exposing at least a part of the surface of the second semiconductor chip, an insulation layer that is formed on the surface of the second semiconductor chip and a surface of the sealing part adjacent to the surface of the second semiconductor chip, and a second wiring that is connected to the pad via an opening disposed in the insulation layer and formed adjacent to the insulation layer, and transmits the signal. The connection part is disposed between the substrate and the sealing part and connects the first wiring and the second wiring to each other.

### TECHNICAL FIELD

The present disclosure relates to a semiconductor apparatus, an imaging apparatus, and a method of producing a semiconductor apparatus. Specifically, the present disclosure relates to a semiconductor apparatus formed by stacking semiconductor chips, an imaging apparatus adopting the configuration, and a method of producing the semiconductor apparatus.

### BACKGROUND ART

In the past, a semiconductor apparatus formed by stacking two semiconductor chips has been used. By disposing a plurality of semiconductor chips three-dimensionally, the semiconductor apparatus can be miniaturized. As such a semiconductor apparatus, for example, there has been proposed an imaging apparatus formed by stacking an image sensor package configured by mounting an image sensor on a substrate and an image processing package configured by mounting an image processing chip on a substrate (see, for example, Patent Literature 1.).

In this imaging apparatus, the image sensor is flip-chip mounted on the substrate in the image sensor package, and the image processing chip is flip-chip mounted on the substrate in the image processing package and sealed by a sealing material. The image sensor package and the image processing package are disposed at positions where the image sensor and the image processing chip face each other, and spherically-formed solders are disposed between wirings disposed on the respective substrates, so that the respective packages are mechanically and electrically connected to each other. At this time, a gap is formed between the image sensor and the image processing chip to reduce thermal conductivity.

### CITATION LIST

### Patent Literature

Patent Literature 1: WO 2017/122449

### DISCLOSURE OF INVENTION

### Technical Problem

In the existing technology described above, a problem that the height of the semiconductor apparatus is increased occurs because two substrates disposed on the respective packages are stacked.

The present disclosure has been made in view of the above-mentioned problem, and it is an object of the present disclosure to reduce the height of a semiconductor apparatus formed by stacking semiconductor chips.

### Solution to Problem

The present disclosure has been made to solve the above-mentioned problem, and a first embodiment thereof is a semiconductor apparatus, including: a first package that includes a substrate on which a first semiconductor chip and a first wiring connected to the first semiconductor chip are disposed; a second package that includes a second semiconductor chip that exchanges a signal with the first semiconductor chip and has a surface on which a pad for transmitting the signal is formed, a sealing part that covers the second semiconductor chip while exposing at least a part of the surface of the second semiconductor chip, an insulation layer that is formed on the surface of the second semiconductor chip and a surface of the sealing part adjacent to the surface of the second semiconductor chip, and a second wiring that is connected to the pad via an opening disposed in the insulation layer and formed adjacent to the insulation layer, and transmits the signal; and a connection part that is disposed between the substrate and the sealing part and connects the first wiring and the second wiring to each other.

Further, in this first embodiment, the sealing part may include a recessed portion in a region facing the first semiconductor chip.

Further, in this first embodiment, the second semiconductor chip may be disposed between the recessed portion and the insulation layer.

Further, in this first embodiment, the second semiconductor chip may be disposed in a vicinity of a side surface of the recessed portion.

Further, in this first embodiment, the recessed portion may be formed such that a second sealing part in which an opening corresponding to the recessed portion is formed is disposed adjacent to the sealing part.

Further, in this first embodiment, the recessed portion may be formed by disposing the second semiconductor chip on a support substrate where a projecting portion to be fitted to the recessed portion is formed, disposing the sealing part to have a shape covering the second semiconductor chip, and then removing the support substrate.

Further, in this first embodiment, the sealing part may include a via plug that penetrates the sealing part itself.

Further, in this first embodiment, the via plug may be connected to the second wiring, and the connection part may connect the first wiring and the second wiring to each other via the via plug.

Further, in this first embodiment, the sealing part may include a recessed portion in a region facing the first semiconductor chip, and the via plug may be disposed in the recessed portion.

Further, in this first embodiment, the semiconductor apparatus may further include a metal film disposed in a region that is adjacent to the via plug and faces the first semiconductor chip.

Further, a second embodiment of the present disclosure is an imaging apparatus, including: a first package that includes a substrate on which an image sensor that generates an image signal on a basis of incident light and a first wiring connected to the image sensor are disposed; a second package that includes a second semiconductor chip that exchanges a signal with the image sensor and has a surface on which a pad for transmitting the signal is formed, a sealing part that covers the second semiconductor chip while exposing at least a part of the surface of the second semiconductor chip, an insulation layer that is formed on the surface of the second semiconductor chip and a surface of the sealing part adjacent to the surface of the second semiconductor chip, and a second wiring that is connected to the pad via an opening disposed in the insulation layer and formed adjacent to the insulation layer, and transmits the signal; and a connection part that is disposed between the substrate and the sealing part and connects the first wiring and the second wiring to each other.

Further, in this second embodiment, the substrate may be formed of a transparent member, and the image sensor may generate the image signal on the basis of the incident light transmitted through the substrate.

Further, a third embodiment of the present disclosure is a method of producing a semiconductor apparatus including: a method of producing a semiconductor apparatus, including: a sealing step of disposing a sealing part that covers a second semiconductor chip that exchanges a signal with a first semiconductor chip of a first package and has a surface on which a pad for transmitting the signal is formed while exposing at least a part of the surface of the second semiconductor chip, the first package including a substrate on which the first semiconductor chip and a first wiring connected to the first semiconductor chip are disposed; a second package producing step including an insulation layer forming step of forming an insulation layer on the surface of the second semiconductor chip and a surface of the sealing part adjacent to the surface of the second semiconductor chip, and a second wiring forming step of forming a second wiring that is connected to the pad via an opening disposed in the insulation layer and formed adjacent to the insulation layer, and transmits the signal; and a connection step of connecting, by a connection part that is disposed between the substrate and the sealing part, the first wiring and the second wiring to each other.

In such embodiments, the insulation layer and the wiring layer are formed adjacent to the second semiconductor chip and the sealing part in the second package to achieve the effect that the wiring of the pad of the second semiconductor chip is rewired in the region of the sealing part. In the second package, the substrate is omitted and the height is assumed to be reduced.

### BRIEF DESCRIPTION OF DRAWINGS

FIG. 1 is a diagram showing a configuration example of a semiconductor apparatus according to an embodiment of the present disclosure.

FIG. 2 is a diagram showing a configuration example of an imaging apparatus according to a first embodiment of the present disclosure.

FIG. 3 is a diagram showing an example of a method of producing an imaging apparatus according to the first embodiment of the present disclosure.

FIG. 4 is a diagram showing an example of the method of producing an imaging apparatus according to the first embodiment of the present disclosure.

FIG. 5 is a diagram showing an example of the method of producing an imaging apparatus according to the first embodiment of the present disclosure.

FIG. 6 is a diagram showing an example of the method of producing an imaging apparatus according to the first embodiment of the present disclosure.

FIG. 7 is a diagram showing a configuration example of an imaging apparatus according to a second embodiment of the present disclosure.

FIG. 8 is a diagram showing an example of a method of producing an imaging apparatus according to the second embodiment of the present disclosure.

FIG. 9 is a diagram showing a configuration example of an imaging apparatus according to a third embodiment of the present disclosure.

FIG. 10 is a diagram showing an example of a method of producing an imaging apparatus according to the third embodiment of the present disclosure.

FIG. 11 is a diagram showing a configuration example of an imaging apparatus according to a fourth embodiment of the present disclosure.

FIG. 12 is a diagram showing a configuration example of an imaging apparatus according to a fifth embodiment of the present disclosure.

FIG. 13 is a diagram showing an example of a method of producing an imaging apparatus according to the fifth embodiment of the present disclosure.

FIG. 14 is a diagram showing a configuration example of an imaging apparatus according to a sixth embodiment of the present disclosure.

FIG. 15 is a block diagram showing a configuration example of an imaging apparatus according to an embodiment of the present disclosure.

FIG. 16 is a block diagram showing an example of a schematic configuration of a camera that is an example of an imaging apparatus to which the present technology may be applied.

### MODE(S) FOR CARRYING OUT THE INVENTION

Next, embodiments for carrying out the present disclosure (hereinafter, referred to as embodiments) will be described with reference to the drawings. In the following drawings, the same or similar portions will be denoted by the same or similar reference symbols. Further, the embodiments will be described in the following order.

1. First Embodiment

2. Second Embodiment

3. Third Embodiment

4. Fourth Embodiment

5. Fifth Embodiment

6. Sixth Embodiment

7. Configuration example of imaging apparatus

8. Application example to camera

### 1. First Embodiment

### Configuration of Semiconductor Apparatus

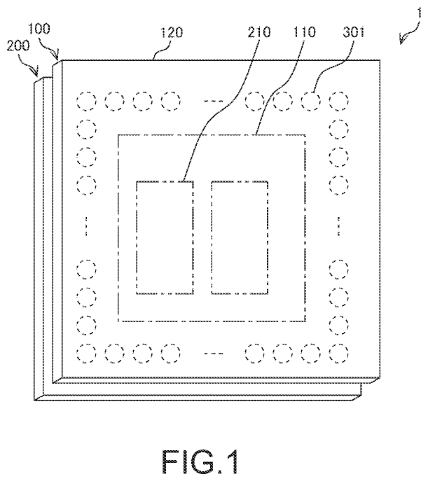

FIG. 1 is a diagram showing a configuration example of a semiconductor apparatus according to an embodiment of the present disclosure. FIG. 1 is a diagram showing a configuration example of an imaging apparatus 1. A semiconductor apparatus according to the embodiment of the present disclosure is described taking the imaging apparatus 1 in FIG. 1 as an example. The imaging apparatus 1 in FIG. 1 includes a first package 100, a second package 200, and a connection part 301.

The first package 100 is a package formed by mounting an image sensor 110 on a substrate 120. The image sensor 110 is mounted on the surface (the back side of the paper in FIG. 1) of the substrate 120.

Meanwhile, the second package 200 is configured as a fan-out wafer level package (FOWLP) including an imaging control chip 210 described below.

This FOWLP is a package in which a substrate is omitted, the imaging control chip 210 is embedded in a sealing part (sealing part 220), and the re-wiring region for drawing a wiring from a terminal (pad) formed on the surface of the imaging control chip 210 is extended to the region of the sealing part around the imaging control chip 210. This is a package in which the wiring region can be widened and a semiconductor chip including many terminals can be easily mounted as compared with a CSP (Chip Size Package). Further, the re-wiring region can be formed by a wafer process and can be miniaturized. The second package 200 in FIG. 1 represents an example including two imaging control chips 210.

The connection part 301 electrically connects the first package 100 and the second package 200 to each other. As this connection part 301, for example, a solder ball formed in a spherical shape can be used. The imaging apparatus 1 in FIG. 1 represents an example in which a plurality of connection parts 301 is disposed in the first package 100 and the second package 200. Note that the imaging apparatus 1 is an example of the semiconductor apparatus described in the claims.

[Configuration of Imaging Apparatus]

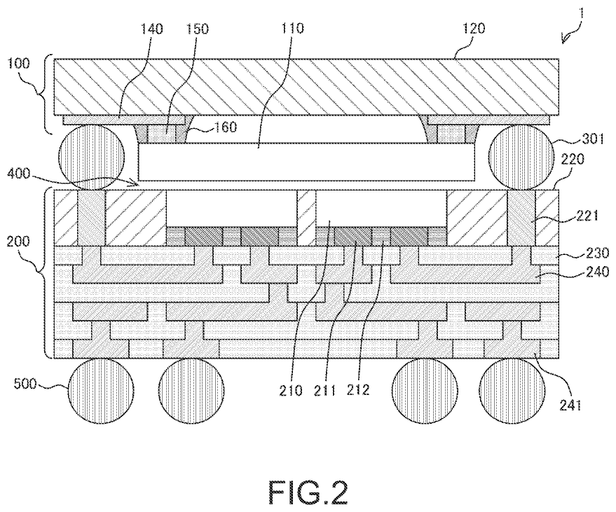

FIG. 2 is a diagram showing a configuration example of an imaging apparatus according to a first embodiment of the present disclosure. FIG. 2 is a cross-sectional view showing a configuration example of the imaging apparatus 1 described in FIG. 1.

The first package 100 includes the image sensor 110, the substrate 120, a wiring 140, a bump 150, and an adhesive 160.

The image sensor 110 is a semiconductor chip formed by arranging pixels each including a photoelectric conversion unit for converting applied light into an electrical signal in a two-dimensional grid pattern. This image sensor 110 generates an image signal, which is a signal based on applied light from a subject, and performs imaging. The generated image signal is transmitted to the imaging control chip 210 described below. Further, the image sensor 110 in FIG. 2 captures an image of incident light transmitted through the substrate 120.

The bump 150 electrically connects the image sensor 110 and the wiring 140 to each other. This bump 150 can be formed of, for example, copper (Cu) or other metals formed in a columnar shape on a pad (not shown) of the image sensor 110. For example, a bump formed of Cu formed in a columnar shape by a plating method, a bump including a solder formed by reflow, a stud bump including a gold (Au) wire, or the like can be used as the bump 150.

The substrate 120 is a substrate on which the image sensor 110 is mounted. A wiring (the wiring 140) is disposed on the surface of the substrate 120 in FIG. 2, and the image sensor 110 is flip-chip mounted on this surface. Further, the substrate 120 in FIG. 2 is formed of a transparent member such as glass. Incident light transmitted through this substrate 120 is applied to a light-receiving surface, which is the surface of the image sensor 110 on which pixels are arranged.

The wiring 140 is a wiring that is disposed on the surface of the substrate 120. This wiring 140 is electrically connected to the image sensor 110 to transmit a signal. Specifically, the wiring 140 is connected to the image sensor 110 via the bump 150. An image signal output by the image sensor 110 or a control signal input to the image sensor 110 corresponds to this signal. The wiring 140 can be formed of, for example, a metal such as Cu.

The adhesive 160 is for adhering the image sensor 110 to the substrate 120. This adhesive 160 is disposed in the periphery of the image sensor 110 and adheres the image sensor 110 to the substrate 120. This protects the connection between the image sensor 110 and the wiring 140 by the bump 150 described above. Further, the light-receiving surface of the image sensor 110 can be hermetically sealed by the adhesive 160 and the substrate 120. For example, an epoxy resin can be used for the adhesive 160.

Note that the image sensor 110 is an example of the first semiconductor chip described in the claims. The wiring 140 is an example of the first wiring described in the claims.

The second package 200 includes the imaging control chip 210, the sealing part 220, an insulation layer 230, and a wiring layer 240.

The imaging control chip 210 is a semiconductor chip for controlling imaging in the image sensor 110. This imaging control chip 210 controls imaging by generating a control signal and outputting the generated control signal to the image sensor 110. Further, the imaging control chip 210 is capable of also processing an image signal generated by the image sensor 110. Further, the imaging control chip 210 can also include a memory for storing the image signal. Further, although FIG. 2 shows an example in which a plurality of imaging control chips 210 is disposed, a configuration in which one imaging control chip 210 is disposed can also be adopted. An insulation film 212 is disposed on the surface of the imaging control chip 210. This insulation film 212 is a film that is formed of, for example, silicon nitride (SiN) and protects and insulates the surface of the imaging control chip 210. Further, a pad 211 is formed on the surface of the imaging control chip 210. This pad 211 is an electrode for transmitting a signal or the like to the imaging control chip 210, and is disposed in an opening formed in the insulation film 212.

The sealing part 220 is for sealing the imaging control chip 210. This sealing part 220 is formed in a shape covering the imaging control chip 210 while exposing at least a part of the surface of the imaging control chip 210. That is, the imaging control chip 210 is disposed in a shape embedded in the sealing part 220 while exposing at least a part of the surface of the imaging control chip 210. In FIG. 2, the sealing part 220 is formed in a shape covering the side surface of the imaging control chip 210 while exposing the surface of the imaging control chip 210. The sealing part 220 can be formed of, for example, an epoxy resin or a polyimide resin. Further, in order to improve the intensity of the sealing part 220, a filler can also be dispersed in these resins. Further, a via plug 221 is disposed in the sealing part 220 in FIG. 2. This via plug 221 is formed in a shape penetrating the sealing part 220 and is connected to the wiring layer 240 described below. The via plug 221 can be formed of, for example, a metal formed in a columnar shape.

The insulation layer 230 is for insulating the wiring layer 240 described below. This insulation layer 230 is formed on the surface of the imaging control chip 210 and on the surface of the sealing part 220 adjacent to the surface of the imaging control chip 210. Assuming that the surface of the sealing part 220 adjacent to the surface of this the imaging control chip 210 is the surface of the sealing part 220, the insulation layer 230 is formed adjacent to the surfaces of the imaging control chip 210 and the sealing part 220. In the insulation layer 230 in FIG. 2, an opening is formed in a region adjacent to the pad 211 of the imaging control chip 210. The insulation layer 230 can be formed of, for example, an epoxy resin, a polyimide resin, an acrylic resin, or a phenol resin.

The wiring layer 240 is a wiring for transmitting a signal transmitted/received to/from the image sensor 110. This wiring layer 240 is connected to the pad 211 of the imaging control chip 210 via the opening formed in the insulation layer 230 and formed adjacent to the insulation layer 230. The wiring layer 240 in FIG. 2 is connected to the via plug 221 and a pad 241 described below. The wiring layer 240 and the insulation layer 230 can have also a multi-layered configuration. In other words, a plurality of wiring layers 240 and a plurality of insulation layers 230 can be stacked to constitute a multilayer wiring. FIG. 2 represents an example in which the wiring layer 240 and the insulation layer 230 include two layers. Further, the pad 241 is disposed on the insulation layer 230 that is the outermost layer. The pad 241 is connected to the wiring layer 240 disposed in the inner layer. The imaging apparatus 1 exchanges signals with an external circuit. The pad 241 is an electrode for transmitting signals at that time. The wiring layer 240 can be formed of, for example, Cu, gold (Au), nickel (Ni), chromium (Cr), or palladium (Pd).

As shown in FIG. 2, the pad 211 disposed on the surface of the imaging control chip 210 is connected to the via plug 221 disposed in the region of the sealing part 220 outside the imaging control chip 210 and to the pad 241 by the wiring layer 240. This re-disposes the pad 211 in the region outside the imaging control chip 210. The wiring layer 240 that re-disposes the pad disposed in the imaging control chip 210 in this way is referred to as a re-wiring layer. Further, a package formed by expanding the re-wiring region to the region of the sealing part 220 is referred to as a FOWLP. The imaging control chip 210 including a large number of pads 211 can be mounted on the package 200 of the same size as the CSP. Further, a larger pad 241 as compared with the pad 211 can be disposed.

Further, since the substrate 120 in the first package 100 can be omitted, the height of the second package 200 can be reduced.

A connection part 500 is disposed on the pad 241. As this connection part 500, a solder ball can be used.

Note that the imaging control chip 210 is an example of the second semiconductor chip described in the claims. The wiring layer 240 is an example of the second wiring layer described in the claims.

The connection part 301 connects the first package 100 and the second package 200 to each other. Specifically, the connection part 301 connects the wiring 140 of the first package 100 and the via plug 221 of the second package 200 to each other. As described above, a solder ball can be used as this connection part 301. Further, as shown in FIG. 2, the first package 100 and the second package 200 are disposed at positions where the image sensor 110 and the imaging control chip 210 face each other and are connected to each other by the connection part 301. At this time, a gap 400 is formed between the image sensor 110 and the imaging control chip 210. This gap 400 makes it possible to insulate the image sensor 110 and the imaging control chip 210. The connection part 301 needs to be formed to have a thickness (height) that is the sum of the thicknesses of the gap 400, the image sensor 110, and the bump 150. This is for providing a space between the substrate 120 and the sealing part 220.

[Method of Producing Imaging Apparatus]

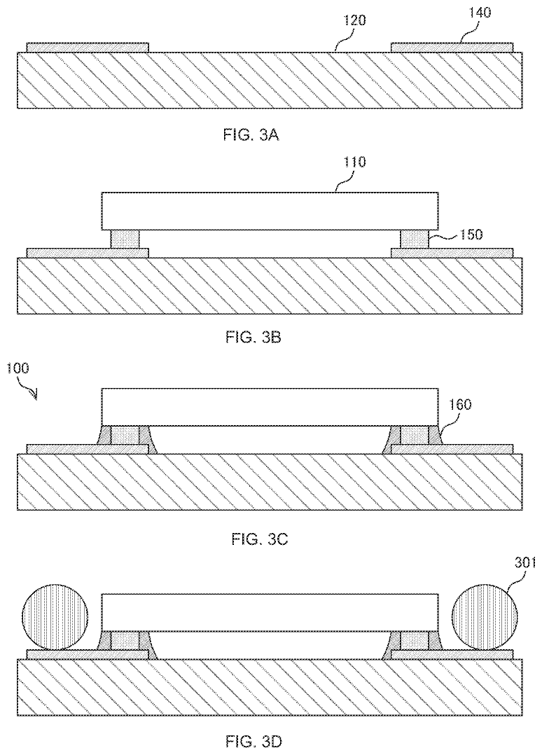

A method of producing the imaging apparatus 1 will be described with reference to FIG. 3 to FIG. 6.

[Method of Producing First Package]

FIG. 3 is a diagram showing an example of a method of producing an imaging apparatus according to a first embodiment of the present disclosure. FIG. 3 is a diagram showing an example of a step of producing the first package 100, of steps of producing the imaging apparatus 1. First, the wiring 140 is formed on the substrate 120 (Part A of FIG. 3). The wiring 140 can be formed by a known method. Next, the image sensor 110 on which the bump 150 is disposed is mounted on the substrate 120 (Part B of FIG. 3). This can be performed by pressure welding in the case of the bump 150 formed of Au or the like, and by melting solder in the case of the bump 150 formed of solder or the like. Next, the adhesive 160 is disposed (Part C of FIG. 3). This can be performed by applying the adhesive 160 by a dispenser or the like and curing the applied adhesive 160. In this way, the first package 100 can be produced.

Next, the connection part 301 is disposed on the wiring 140 (Part D of FIG. 3). This can be performed by, for example, disposing the connection part 301 on the wiring 140 to which flux is applied and melting the solder forming the connection part 301.

[Method of Producing Second Package]

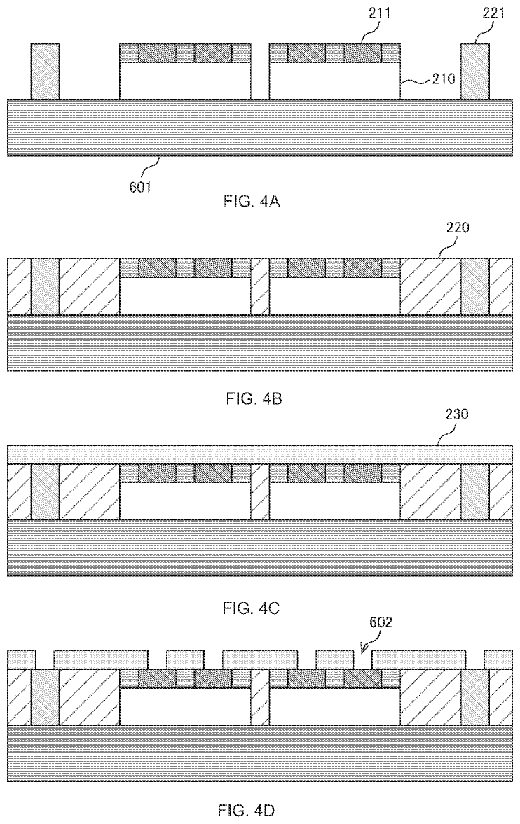

FIG. 4 to FIG. 6 are each a diagram showing an example of the method of producing an imaging apparatus according to the first embodiment of the present disclosure. FIG. 4 to FIG. 6 are each a diagram showing an example of the step of producing the second package 200. First, the imaging control chip 210 and the via plug 221 are disposed on a support substrate 601. Here, the support substrate 601 is a substrate for supporting the imaging control chip 210 and the like in the step of producing the second package 200. The imaging control chip 210 on which the pad 211 is formed is disposed on the support substrate 601. At this time, the imaging control chip 210 is disposed in an orientation in which the back surface, which is a surface different from the surface on which the pad 211 is formed, is adjacent to the support substrate 601 (Part E of FIG. 4).

Next, the sealing part 220 is disposed around the imaging control chip 210 and the via plug 221 (Part F of FIG. 4). This can be performed by, for example, disposing a liquid sealing part 220 by a coating method or a screen printing method and curing the sealing part 220. Alternatively, the sealing part 220 can be formed by a molding method using mold. This step is an example of the sealing step described in the claims.

Next, the insulation layer 230 is formed adjacent to the surface of the imaging control chip 210, the surface of the sealing part 220, and the surface of the via plug 221 (Part G in FIG. 4). This can be formed by, for example, a coating method. Next, an opening 602 is formed at a position where the pad 211 of the imaging control chip 210 and the via plug 221 are disposed (Part H of FIG. 4). This can be formed by forming a resist by photolithography and performing etching using this resist as a mask. Note that in the case where a photosensitive resist is applied to the insulation layer 230, the opening 602 can be formed by performing exposure and development after forming the insulation layer 230. This step is an example of the step of forming an insulation layer described in the claims.

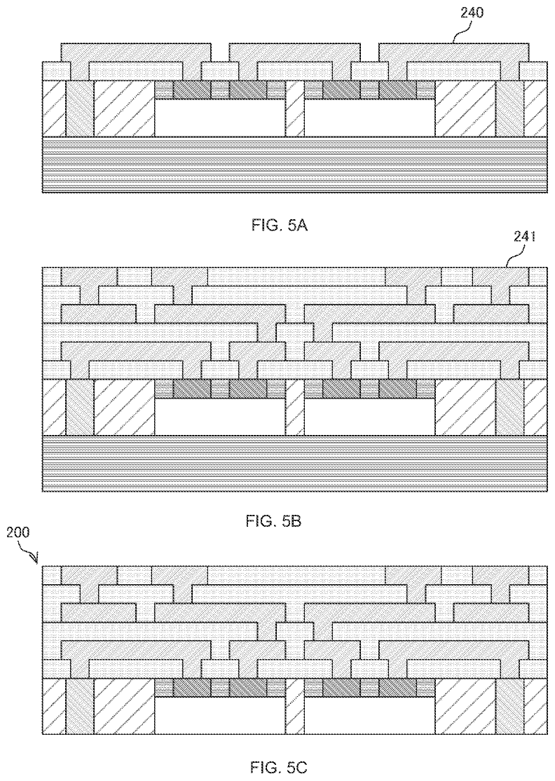

Next, the wiring layer 240 is formed adjacent to the insulation layer 230. At this time, the wiring layer 240 is formed adjacent to the pad 211 via the opening 602 formed in the insulation layer 230 (Part I of FIG. 5). This can be formed by a plating method. Specifically, a barrier layer formed of Ti or the like and a seed layer formed of Cu or the like are sequentially stacked on the surface of the insulation layer 230 by a sputtering method or the like, a mask by a resist formed by photolithography is disposed, and a Cu layer is formed by plating. Next, the resist is peeled off and the barrier layer and the seed layer of portions where the Cu layer by plating is not formed are removed, thereby forming the wiring layer 240. This step is an example of forming the second wiring layer described in the claims.

Formation of the insulation layer 230 and the wiring layer 240 is performed a plurality of times to form the wiring layer 240 having a multilayer and to form the pad 241 (Part J of FIG. 5). Next, the support substrate 601 is removed (Part K of FIG. 5). By the above-mentioned step, the second package 200 can be formed. This process is an example of the of forming the second package described in the claims.

Next, the connection part 500 is disposed on the pad 241 of the second package 200. This can be performed in a way similar to that of the connection part 301. Next, the first package 100 is disposed on the second package 200 while aligning the via plug 221 of the inverted second package 200 with the connection part 301 disposed on the first package 100.

Finally, the wiring 140 of the first package 100 and the via plug 221 of the second package 200 are connected to each other by the connection part 301. Specifically, the connection part 301 is re-melted and bonded to the via plug 221 to which flux is applied. The step is an example of the connection step described in the claims.

By the above-mentioned steps, the produced first package 100 and the produced second package 200 can be combined to produce the imaging apparatus 1.

As described above, the imaging apparatus 1 according to the first embodiment of the present disclosure can be reduced in height by disposing the second package 200 configured as a fan-out wafer level package.

### 2. Second Embodiment

In the imaging apparatus 1 according to the first embodiment described above, the surface of the second package 200 facing the first package 100 is formed to be a flat surface. Meanwhile, the imaging apparatus 1 according to the second embodiment of the present disclosure is different from the first embodiment described above in that a recessed portion is provided on the surface of the second package 200 facing the first package 100.

[Configuration of Imaging Apparatus]

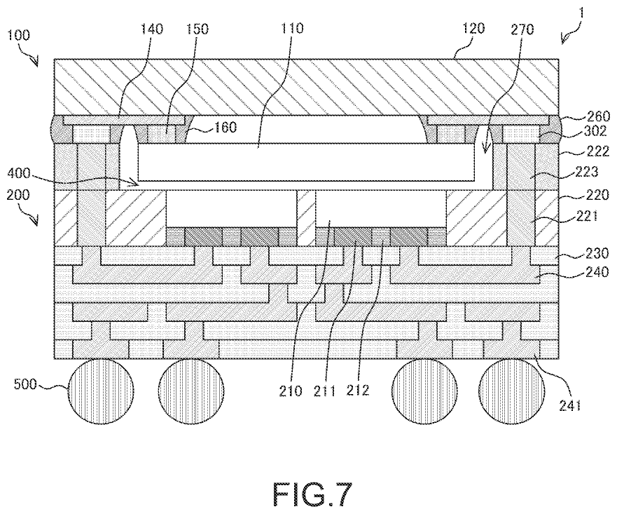

FIG. 7 is a diagram showing a configuration example of an imaging apparatus according to a second embodiment of the present disclosure. FIG. 7 is a cross-sectional view showing a configuration example of the imaging apparatus 1 similarly to FIG. 1. The imaging apparatus 1 in FIG. 7 is different from the imaging apparatus 1 described in FIG. 1 in that a recessed portion 270 is disposed on the surface of the second package 200 facing the imaging control chip 210 and the first package 100 and the second package 200 are connected to each other by a connection part 302.

As described above, the recessed portion 270 is disposed in the second package 200. This recessed portion 270 can be formed by disposing a second sealing part 222 on the surface of the sealing part 220 of the second package 200 facing the first package 100. This second sealing part 222 can be formed of a frame-shaped resin. Specifically, the second sealing part 222 can be formed of a rectangular resin having an opening formed at a position corresponding to the recessed portion 270. Further, a via plug 223 is disposed in this second sealing part 222. This via plug 223 penetrates the second sealing part 222 and is bound to the via plug 221. By disposing the via plug 223, the via plug 221 can be extended to the surface of the second sealing part 222. Similarly to the via plug 221, the via plug 223 can be formed of a metal such as Cu.

In FIG. 7, the imaging control chip 210 is disposed adjacent to the bottom surface of the recessed portion 270. The imaging control chip 210 is disposed in the region of the sealing part 222 between the recessed portion 270 and the insulation layer 230.

The image sensor 110 of the first package 100 can be accommodated in the recessed portion 270 thus formed. This makes it possible to further reduce the height of the imaging apparatus 1 while providing the gap 400 between the image sensor 110 and the imaging control chip 210. Note that as the connection part 302, a thin anisotropic conductive film (ACF) can be used in place of the solder ball. This is because the image sensor 110 is accommodated in the recessed portion 270, and the space between the substrate 120 and the second sealing part 222 can be narrowed. Further, a bump similar to the bump 150 in FIG. 7 can be formed and used as the connection part 302. By disposing the connection part 302 instead of the connection part 301, the wiring length between the first package 100 and the second package 200 can be shortened, and the delay time of the transmission of signals can be shortened.

Note that in the imaging apparatus 1 in FIG. 7, an adhesive 260 is further disposed. This adhesive 260 is disposed between the substrate 120 and the second sealing part 222 to adhere the substrate 120 and the second sealing part 222. By disposing the adhesive 260 between the substrate 120 and the second sealing part 222, the image sensor 110 can be hermetically sealed. Further, the adhesive 260 is disposed to have a shape covering the connection part 302 and protects the bonding by the connection part 302.

[Method of Producing Second Package]

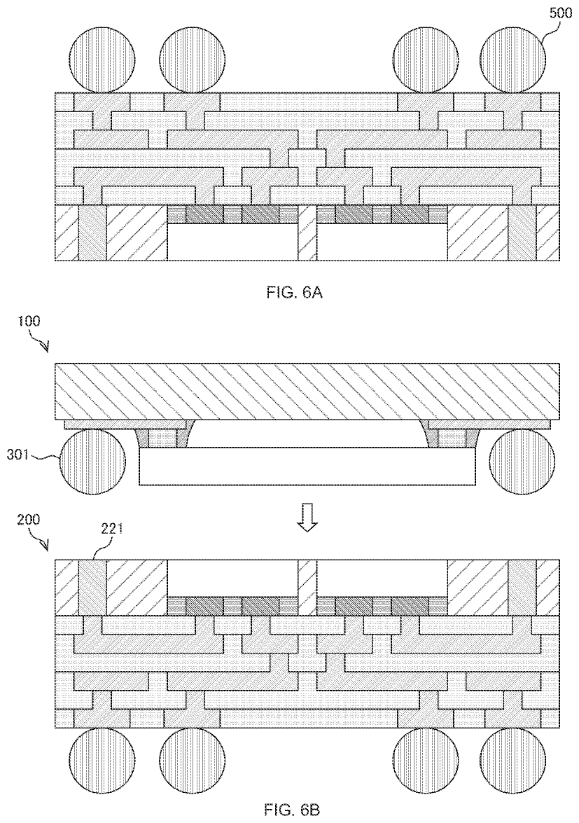

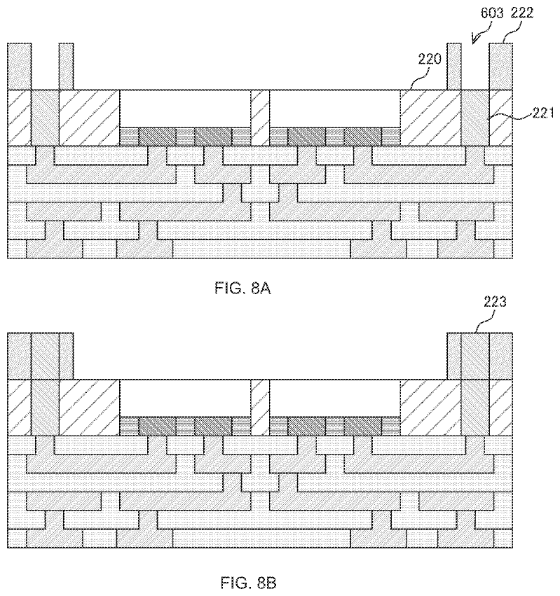

FIG. 8 is a diagram showing an example of a method of producing an imaging apparatus according to the second embodiment of the present disclosure. FIG. 8 is a diagram showing an example of a step of producing the second package 200, which is a step executed between the step of Part K of FIG. 5 and the step of Part L of FIG. 6.

In Part A of FIG. 8, the second sealing part 222 is disposed on the sealing part 220 of the second package 200. This can be performed by adhering the second sealing part 222 to the sealing part 220 by an adhesive (not shown). Next, an opening 603 is formed at a position adjacent to the via plug 221 of the second sealing part 222. This can be performed by etching the second sealing part 222 (Part A of FIG. 8).

Next, the via plug 223 is disposed in the opening 603 (Part B of FIG. 8). This can be performed by, for example, embedding a columnar metal such as Cu using a plating method or the like. After that, instead of the connection part 301, the connection part 302 is disposed between the wiring 140 and the via plug 223 and bonded, thereby making it possible to produce the imaging apparatus 1.

Since the other configuration of the imaging apparatus 1 is similar to the configuration of the imaging apparatus 1 described in the first embodiment of the present disclosure, description thereof is omitted.

As described above, in the imaging apparatus 1 according to the second embodiment of the present disclosure, the recessed portion 270 is disposed on the sealing part 220 of the second package 200, and the image sensor 110 of the first package 100 is accommodated in this recessed portion 270. This makes it possible to reduce the height of the imaging apparatus 1.

### 3. Third Embodiment

In the imaging apparatus 1 according to the second embodiment described above, the recessed portion 270 is formed by disposing the second sealing part 222 on the surface of the sealing part 220 formed to be flat. Meanwhile, the imaging apparatus 1 according to the third embodiment of the present disclosure is different from the above-mentioned second embodiment in that a recessed portion is formed in the sealing part itself.

[Configuration of Imaging Apparatus]

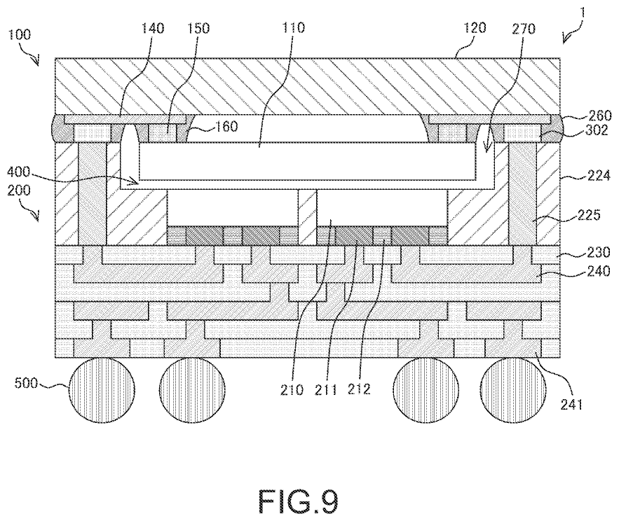

FIG. 9 is a diagram showing a configuration example of an imaging apparatus according to a third embodiment of the present disclosure. FIG. 9 is a cross-sectional view showing a configuration example of the imaging apparatus 1 similarly to FIG. 7. The imaging apparatus 1 in FIG. 9 is different from the imaging apparatus 1 described in FIG. 7 in that the second sealing part 222 is omitted and a sealing part 224 is disposed instead of the sealing part 220.

The sealing part 224 seals the imaging control chip 210 similarly to the sealing part 220. This sealing part 224 is formed thicker than the sealing part 220, and the recessed portion 270 is formed in the sealing part 224. The image sensor 110 is accommodated in this recessed portion 270. Instead of the via plug 223, a via plug 225 is disposed in the sealing part 224. This via plug 225 is a via plug formed to have a larger thickness (height) than the via plug 223.

[Method of Producing Second Package]

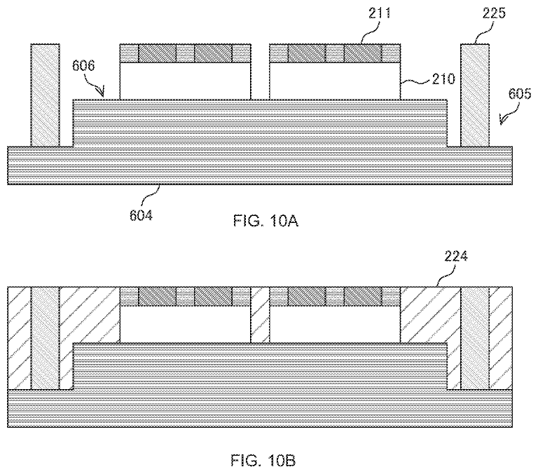

FIG. 10 is a diagram showing an example of a method of producing an imaging apparatus according to the third embodiment of the present disclosure. FIG. 10 is a diagram showing an example of a step of producing the second package 200, which is a step executed instead of Part E and Part F in FIG. 4.

In Part A of FIG. 10, a support substrate 604 is used instead of the support substrate 601, and the imaging control chip 210 and the via plug 225 are disposed. This support substrate 604 is a support substrate in which a step 605 is formed around the support substrate 604 and a projecting portion 606 is disposed in the center. This projecting portion 606 is formed in a shape to be fitted with the recessed portion 270. The imaging control chip 210 is disposed on the projecting portion 606, and the via plug 225 is disposed on the step 605 (Part A in FIG. 10).

Next, the sealing part 224 is disposed similarly to Part F of FIG. 4 (Part B of FIG. 10). After that, by removing the support substrate 604, the recessed portion 270 having a depth corresponding to the height of the projecting portion 606 is formed in the sealing part 224. Steps such as bonding of the second sealing part 222 can be omitted, and the step of producing the imaging apparatus 1 can be simplified.

Since the other configuration of the imaging apparatus 1 is similar to the configuration of the imaging apparatus 1 described in the second embodiment of the present disclosure, description thereof is omitted.

As described above, in the imaging apparatus 1 according to the third embodiment of the present disclosure, it is possible to simplify the step of producing the imaging apparatus 1 by disposing the sealing part 224 in which the recessed portion 270 is formed.

### 4. Fourth Embodiment

In the imaging apparatus 1 according to the second embodiment described above, the image sensor 110 and the second package 200 are disposed to face each other with the gap 400 therebetween. Meanwhile, the imaging apparatus 1 according to a fourth embodiment of the present disclosure is different from the above-mentioned second embodiment in that a metal film is further disposed on the surface of the second package 200 facing the image sensor 110.

[Configuration of Imaging Apparatus]

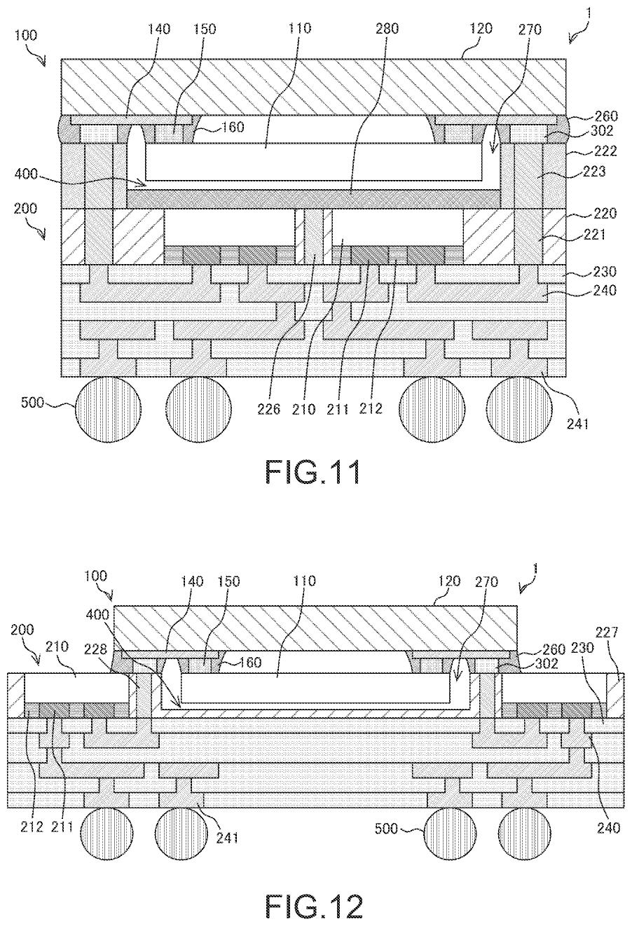

FIG. 11 is a diagram showing a configuration example of the imaging apparatus according to the fourth embodiment of the present disclosure. FIG. 11 is a cross-sectional view showing a configuration example of the imaging apparatus 1 similarly to FIG. 7. The imaging apparatus 1 in FIG. 11 is different from the imaging apparatus 1 described in FIG. 7 in that a metal film 280 and a via plug 226 are further provided.

The metal film 280 is a metal film disposed on the surface of the second package 200 facing the image sensor 110 of the first package 100. The metal film 280 in FIG. 11 is disposed on the bottom surface of the recessed portion 270 of the second package 200. This metal film 280 is for transferring the radiation heat from the image sensor 110 to dissipate the heat from the image sensor 110. The metal film 280 can be formed of Cu or the like.

The via plug 226 is a via plug that constitutes a heat transfer path from the surface of the sealing part 220 facing the first package 100 to the regions of the insulation layer 230 and the wiring layer 240. The via plug disposed to improve the heat dissipation as described above is referred to as a thermal via. The via plug 226 in FIG. 11 is disposed in the recessed portion 270. Further, the via plug 226 in FIG. 11 is disposed adjacent to the metal film 280. The via plug 226 and the metal film 280 allow the radiation heat from the image sensor 110 to be dissipated to the side where the insulation layer 230 and the wiring layer 240 are disposed. This makes it possible to reduce the temperature rise of the image sensor 110.

Since the other configuration of the imaging apparatus 1 is similar to the configuration of the imaging apparatus 1 described in the second embodiment of the present disclosure, description thereof is omitted.

As described above, in the imaging apparatus 1 according to the fourth embodiment of the present disclosure, by disposing the metal film 280 and the via plug 226, it is possible to constitute the heat dissipation path of the image sensor 110 and reduce the temperature rise of the image sensor 110.

### 5. Fifth Embodiment

In the imaging apparatus 1 according to the third embodiment described above, the imaging control chip 210 has been disposed between the recessed portion 270 and the insulation layer 230. Meanwhile, the imaging apparatus 1 according to the fifth embodiment of the present disclosure is different from the above-mentioned third embodiment in that the imaging control chip 210 is disposed in the vicinity of the side surface of the recessed portion 270.

[Configuration of Imaging Apparatus]

FIG. 12 is a diagram showing a configuration example of the imaging apparatus according to the fifth embodiment of the present disclosure. FIG. 12 is a cross-sectional view showing a configuration example of the imaging apparatus 1 similarly to FIG. 9. The imaging apparatus 1 in FIG. 12 is different from the imaging apparatus 1 described in FIG. 9 in that a sealing part 227 is provided instead of the sealing part 224 of the second package 200 and the imaging control chip 210 is disposed in the vicinity of the side surface of the recessed portion 270.

The sealing part 227 in FIG. 12. is for sealing the imaging control chip 210 similarly to the sealing part 224. Similarly to the sealing part 224, the recessed portion 270 is disposed in the sealing part 227. The imaging control chip 210 in FIG. 12 is disposed in the vicinity of the side surface of the recessed portion 270. Here, the side surface of the recessed portion 270 is a surface adjacent to the bottom surface of the recessed portion 270. The two imaging control chips 210 in FIG. 12 are disposed in the vicinity of the opposed side surfaces of the recessed portion 270. The sealing part 227 is formed by being extended to the region outside the first package 100, and the imaging control chip 210 is disposed in the region. The imaging control chip 210 in FIG. 9 is disposed at a position overlapping with the image sensor 110 in the imaging apparatus 1 in the top view. Meanwhile, the imaging control chip 210 in FIG. 12 is disposed at a position juxtaposed with the image sensor 110 in the top view. For this reason, the sealing part 227 can be formed to have a larger area and a smaller film thickness as compared with the sealing part 224 in FIG. 9. The second package 200 is formed to have a size wider than the first package 100 and is reduced in height.

Note that a via plug 228 is disposed in the sealing part 227, instead of the via plug 225. This via plug 228 is a via plug that is formed to have the same thickness (height) as the thickness of the imaging control chip 210. Signals are transmitted between the image sensor 110 and the imaging control chip 210 via the via plug 228 and the wiring layer 240. As shown in FIG. 12, since the imaging control chip 210 is disposed close to the connection part 302, the transmission path of signals is shortened as compared with the second package 200 in FIG. 9. This makes it possible to transmit signals at high speed. Further, since the imaging control chip 210 is disposed apart from the image sensor 110, the emission of noise from the imaging control chip 210 to the image sensor 110 is reduced. This makes it possible to reduce the noise in image signals. Similarly, since the imaging control chip 210 is apart from the image sensor 110, the effect of the radiation heat from the imaging control chip 210 is reduced. This makes it possible to reduce temperature rise of the image sensor 110.

Note that the configuration of the imaging apparatus 1 is not limited to this example. For example, a through hole formed by piercing the sealing part 227 on the bottom surface of the recessed portion 270 and the insulation layer 230 can also be disposed. By disposing this through hole, it is possible to prevent the atmosphere of the gap 400 from expanding due to heating when performing reflow soldering. This makes it possible to reduce the deformation of the imaging apparatus 1 during reflow soldering.

[Method of Producing Second Package]

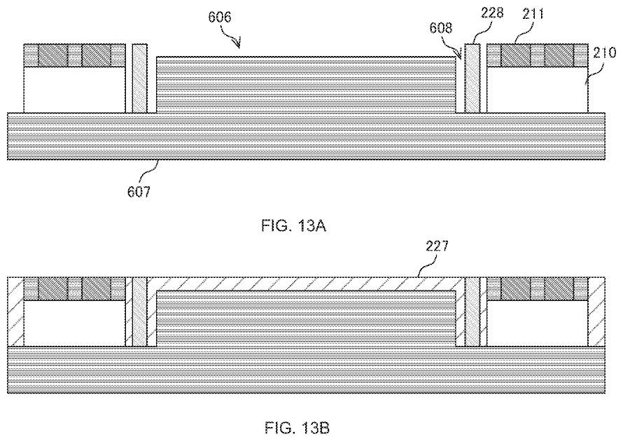

FIG. 13 is a diagram showing an example of a method of producing an imaging apparatus according to the fifth embodiment of the present disclosure. FIG. 13 is a diagram showing an example of a step of producing the second package 200, which is a step executed instead of Part E and Part F of FIG. 4.

In Part A of FIG. 13, a support substrate 607 is used instead of the support substrate 601 in FIG. 4, and the imaging control chip 210 and the via plug 228 are disposed. A step 608 is formed in the periphery of the support substrate 607, and the projecting portion 606 described in FIG. 10 is formed in the center. The imaging control chip 210 and the via plug 228 are disposed on this step 608 (Part A in FIG. 13).

Next, the sealing part 227 is disposed (Part B of FIG. 13). After that, the insulation layer 230 and the wiring layer 240 are formed and the support substrate 607 is removed, thereby forming, in the sealing part 227, the recessed portion 270 having a depth corresponding to the height of the projecting portion 606. This makes it possible to dispose the imaging control chip 210 and the via plug 228 in the vicinity of the side surface of the recessed portion 270.

Since the other configuration of the imaging apparatus 1 is similar to the configuration of the imaging apparatus 1 described in the third embodiment of the present disclosure, description thereof is omitted.

As described above, in the imaging apparatus 1 according to the fifth embodiment of the present disclosure, by disposing the imaging control chip 210 in the vicinity of the side surface of the recessed portion 270 of the sealing part 227, the thickness of the sealing part 227 can be reduced. It is possible to reduce the height of the second package 200, and reduce the height of the imaging apparatus 1.

### 6. Sixth Embodiment

In the imaging apparatus 1 according to the fifth embodiment described above, the imaging control chip 210 is disposed on the second package 200. Meanwhile, the imaging apparatus 1 according to a sixth embodiment of the present disclosure is different from the fifth embodiment described above in that a plurality of semiconductor chips having different thicknesses is disposed in the second package 200.

[Configuration of Imaging Apparatus]

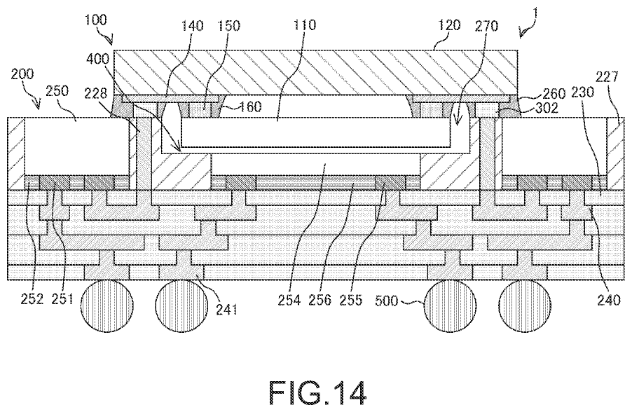

FIG. 14 is a diagram showing a configuration example of the imaging apparatus according to the sixth embodiment of the present disclosure. FIG. 14 is a cross-sectional view showing a configuration example of the imaging apparatus 1 similarly to FIG. 12. The imaging apparatus 1 in FIG. 14 is different from the imaging apparatus 1 described in FIG. 12 in that an imaging control chip 250 is provided instead of the imaging control chip 210 and a memory chip 254 is further provided in the second package 200.

The memory chip 254 is a memory that stores an image signal generated by the image sensor 110. The memory chip 254 includes an insulation film 256 and a pad 255 disposed in an opening of the insulation film 256. The imaging control chip 250 is an imaging control chip formed to have a large height as compared with the memory chip 254. Further, the imaging control chip 250 is a semiconductor chip formed to have a relatively narrow width. The imaging control chip 250 includes an insulation film 252 and a pad 251 disposed in an opening of the insulation film 252. The pads 251 and 255 are connected to the wiring layer 240 described above.

The sealing part 227 in FIG. 14 seals the imaging control chip 250 and the memory chip 254. The memory chip 254 is disposed between the recessed portion 270 and the insulation layer 230, and the imaging control chip 250 is disposed in the vicinity of the side surface of the recessed portion 270. By disposing a relatively thick imaging control chip 250 in the vicinity of the side surface of the recessed portion 270, a relatively thin memory chip 254 can be disposed in the vicinity of the bottom of the recessed portion 270. The thickness of the sealing part 227 can be reduced.

The second package 200 shown in FIG. 14 can be produced by, for example, disposing the imaging control chip 250 in the step 608 of the support substrate 607 shown in Part A of FIG. 13 and disposing the memory chip 254 on the projecting portion 606 of the support substrate 607 to form the sealing part 227.

Note that the configuration of the imaging apparatus 1 is not limited to this example. A semiconductor chip with other functions may be disposed instead of the imaging control chip 250 and the memory chip 254.

Since the other configuration of the imaging apparatus 1 is similar to the configuration of the imaging apparatus 1 described in the fifth embodiment of the present disclosure, description thereof is omitted.

As described above, in the imaging apparatus 1 according to the sixth embodiment of the present disclosure, the imaging control chip 250 is disposed in the vicinity of the side surface of the recessed portion 270 of the sealing part 227 and the memory chip 254 is disposed in the vicinity of the bottom surface of the recessed portion 270 of the sealing part 227. In the case where a plurality of semiconductor chips having different thicknesses is disposed, the semiconductor chip having the smallest thickness is disposed in the vicinity of the bottom surface of the recessed portion 270 of the sealing part 227. This makes it possible to reduce the height of the imaging apparatus 1.

The configuration of the imaging apparatus 1 according to the fourth embodiment of the present disclosure can be applied to other embodiments. Specifically, the metal film 280 and the via plug 226 described in FIG. 11 can be applied to the imaging apparatus 1 in FIGS. 9, 12, and 13.

### 7. Configuration Example of Imaging Apparatus

A configuration example of an imaging apparatus that is an example of the semiconductor apparatus according to the present disclosure will be described.

[Configuration of Imaging Apparatus]

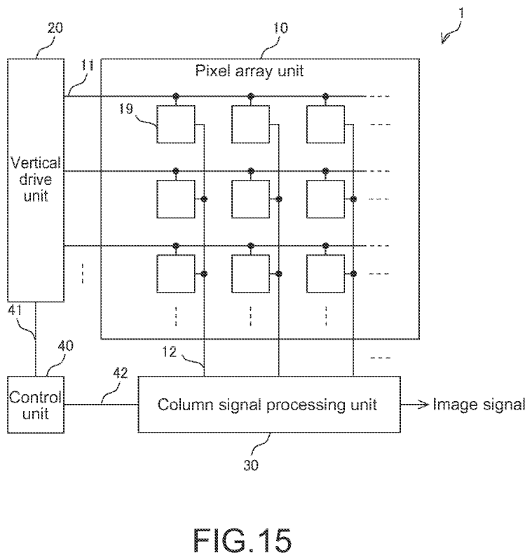

FIG. 15 is a block diagram showing a configuration example of an imaging apparatus according to an embodiment of the present disclosure. The imaging apparatus 1 in FIG. 15 includes a pixel array unit 10, a vertical drive unit 20, a column signal processing unit 30, and a control unit 40.

The pixel array unit 10 is formed by arranging pixels 19 in a two-dimensional grid pattern. Here, the pixel 19 generates an image signal corresponding to the applied light. The pixel 19 includes a photoelectric conversion unit that generates charges corresponding to the applied light. The pixel 19 further includes a pixel circuit. The pixel circuit generates an image signal based on an electric charge generated by the photoelectric converter. Generation of the image signal is controlled by the control signal generated by the vertical drive unit 20 described below. In the pixel array unit 10, signal lines 11 and 12 are arranged in an X-Y matrix pattern. The signal line 11 is a signal line for transmitting a control signal of the pixel circuit in the pixel 19, is arranged for each row of the pixel array unit 10, and is commonly wired with respect to the pixels 19 arranged in each row. The signal line 12 is a signal line for transmitting an image signal generated by the pixel circuit of the pixel 19, is arranged for each column of the pixel array unit 10, and is commonly wired with respect to the pixels 19 arranged in each column. The photoelectric converter and the pixel circuit are formed on a semiconductor substrate.

The vertical drive unit 20 is for generating a control signal of the pixel circuit of the pixel 19. In this vertical drive unit 20, the generated control signal is transmitted to the pixel 19 via the signal line 11 in FIG. 15. The column signal processing unit 30 is for processing the image signal generated by the pixel 19. This column signal processing unit 30 processes the image signal transmitted from the pixel 19 via the signal line 12 in FIG. 15. For example, analog-to-digital conversion for converting an analog image signal generated in the pixel 19 into a digital image signal corresponds to the processing in the column signal processing unit 30. The image signal processed by the column signal processing unit 30 is output as an image signal of the imaging apparatus 1. The control unit 40 is controlling the entire imaging apparatus 1. This control unit 40 controls the imaging apparatus 1 by generating and outputting control signals for controlling the vertical drive unit 20 and the column signal processing unit 30. The control signals generated by the control unit 40 are transmitted to the vertical drive unit 20 and the column signal processing unit 30 by signal lines 41 and 42, respectively.

The pixel array unit 10 of the imaging apparatus 1 in FIG. 15 can be applied to the image sensor 110 described in FIG. 2. Further, the vertical drive unit 20, the column signal processing unit 30, and the control unit 40 of the imaging apparatus 1 in FIG. 15 can be applied to the imaging control chip 210 described in FIG. 2. The pixels 19 arranged in the pixel array unit 10 each include a photoelectric conversion unit and a circuit that handles analogue signals such as a pixel circuit. The pixel 19 includes a relatively slow-speed circuit, and a relatively high power source voltage is applied thereto. Meanwhile, the vertical drive unit 20 and the column signal processing unit 30 generate control signals, process digital image signals that have been analog-to-digital converted, and mainly include logic circuits. These units include high-speed circuits and a relatively low power source voltage is applied thereto.

As described above, the pixel array unit 10 and the vertical drive unit 20, the column signal processing unit 30, and the control unit 40 include circuits having different properties. In this regard, by dividing them into the image sensor 110 and the imaging control chip 210, which are different semiconductor chips, and forming them by processes optimal for the respective circuits, it is possible to improve the performance of the imaging apparatus 1. The pixel array unit 10 in FIG. 15 is disposed in the first package 100, and the vertical drive unit 20, the column signal processing unit 30, and the control unit 40 in FIG. 15 are disposed in the second package 200. By stacking and disposing the first package 100 and the second package 200 and connecting them to each other by the connection part 301, the wiring path between the pixel array unit 10 and the vertical drive unit 20 or the column signal processing unit 30 can be shortened.

Note that the configuration of the imaging apparatus 1 is not limited to this example. For example, the pixel array unit 10 and the vertical drive unit 20 can be applied to the image sensor 110 in FIG. 2, and the column signal processing unit 30 and the control unit 40 can be applied to the imaging control chip 210 in FIG. 2.

### 8. Application Example to Camera

The technology according to the present disclosure (the present technology) can be applied to a variety of products. For example, the present technology may be realized as an image sensor mounted in an imaging apparatus such as a camera.

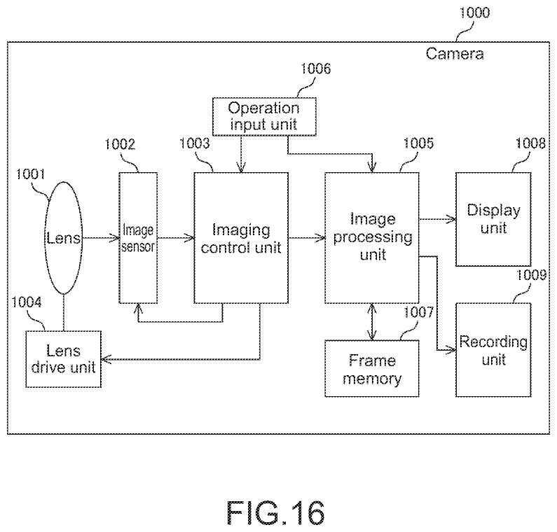

FIG. 16 is a block diagram showing an example of a schematic configuration of a camera that is an example of an imaging apparatus to which the present technology may be applied. A camera 1000 in FIG. 16 includes a lens 1001, an image sensor 1002, an imaging control unit 1003, a lens drive unit 1004, an image processing unit 1005, an operation input unit 1006, a frame memory 1007, a display unit 1008, and a recording unit 1009.

The lens 1001 is an imaging lens of the camera 1000. This lens 1001 condenses light from a subject and causes the light to enter the image sensor 1002 described below to form an image of the subject.

The image sensor 1002 is a semiconductor apparatus for imaging light from a subject condensed by the lens 1001. This image sensor 1002 generates an analog image signal corresponding to the applied light, converts the analog image signal into a digital image signal, and outputs the digital image signal.

The imaging control unit 1003 controls imaging in the image sensor 1002. This imaging control unit 1003 controls the image sensor 1002 by generating a control signal and outputting the generated control signal to the image sensor 1002. Further, the imaging control unit 1003 is capable of performing auto-focus in the camera 1000 on the basis of the image signal output from the image sensor 1002. Here, the auto-focus is a system that detects a focal position of the lens 1001 and automatically adjusts the focal position. As this auto-focus, a method of detecting the focal position by detecting the image plane phase difference by phase difference pixels arranged in the image sensor 1002 (image plane phase difference auto focus) can be used. Further, also a method of detecting, as the focal position, a position where an image exhibits a highest contrast (contrast autofocus) can be applied. The imaging control unit 1003 adjusts the position of the lens 1001 via the lens drive unit 1004 on the basis of the detected focal position, and performs autofocus. Note that the imaging control unit 1003 can be configured by, for example, a DSP (Digital Signal Processor) on which firmware is mounted.

The lens drive unit 1004 is for driving the lens 1001 on the basis of the control of the imaging control unit 1003. This lens drive unit 1004 is capable of driving the lens 1001 by changing the position of the lens 1001 using a built-in motor.

The image processing unit 1005 processes the image signal generated by the image sensor 1002. Demosaicing for generating an image signal of a missing color among image signals that correspond to red, green, and blue for respective pixels, noise reduction for removing noise from an image signal, encoding of an image signal, and the like correspond to the processing. The image processing unit 1005 can include, for example, a microcomputer equipped with firmware.

The operation input unit 1006 accepts an operation input from the user of the camera 1000. For example, a push button or a touch panel can be used as the operation input unit 1006. The operation input accepted by the operation input unit 1006 is transmitted to the imaging control unit 1003 or the image processing unit 1005. After that, processing corresponding to the operation input, such as processing of imaging a subject, is started.

The frame memory 1007 is a memory for storing frames that are image signals for one screen. This frame memory 1007 is controlled by the image processing unit 1005 and maintains frames during image processing.

The display unit 1008 displays an image processed by the image processing unit 1005. As this display unit 1008, for example, a liquid crystal panel can be used.

The recording unit 1009 is for recording the image processed by the image processing unit 1005. As this recording unit 1009, for example, a memory card or a hard disk can be used.

The camera to which the present disclosure can be applied has been described above. The present technology can be applied to the image sensor 1002 of the configurations described above. Specifically, the imaging apparatus 1 described in FIG. 1 can be applied to the image sensor 1002. By applying the imaging apparatus 1 to the image sensor 1002, the height of the image sensor 1002 can be reduced, and the camera 1000 can be miniaturized.

Note that, although the camera has been described as an example here, the technology according to the present disclosure may be applied to, for example, a monitoring apparatus or the like.

Finally, the descriptions of the respective embodiments above are examples of the present disclosure, and the present disclosure is not limited to the embodiments described above. Thus, various modifications may of course be made depending on the design and the like without departing from the technical idea according to the present disclosure even in the case of an embodiment other than the embodiments described above.

Further, the drawings in the above-mentioned embodiments are schematic, and the ratio of the dimensions of each part and the like do not necessarily coincide with actual ones. Further, it goes without saying that a certain figure and another figure have different dimensional relationships and different ratios of dimensions with respect to the same portions.

It should be noted that the present technology may take the following configurations.

(1) A semiconductor apparatus, including:

a first package that includes a substrate on which a first semiconductor chip and a first wiring connected to the first semiconductor chip are disposed;

a second package that includes
a second semiconductor chip that exchanges a signal with the first semiconductor chip and has a surface on which a pad for transmitting the signal is formed,
a sealing part that covers the second semiconductor chip while exposing at least a part of the surface of the second semiconductor chip,
an insulation layer that is formed on the surface of the second semiconductor chip and a surface of the sealing part adjacent to the surface of the second semiconductor chip, and
a second wiring that is connected to the pad via an opening disposed in the insulation layer and formed adjacent to the insulation layer, and transmits the signal; and

a connection part that is disposed between the substrate and the sealing part and connects the first wiring and the second wiring to each other.

(2) The semiconductor apparatus according to (1) above, in which

the sealing part includes a recessed portion in a region facing the first semiconductor chip.

(3) The semiconductor apparatus according to (2) above, in which

the second semiconductor chip is disposed between the recessed portion and the insulation layer.

(4) The semiconductor apparatus according to (2) above, in which

the second semiconductor chip is disposed in a vicinity of a side surface of the recessed portion.

(5) The semiconductor apparatus according to (2) or (3) above, in which

the recessed portion is formed such that a second sealing part in which an opening corresponding to the recessed portion is formed is disposed adjacent to the sealing part.

(6) The semiconductor apparatus according to any one of (2) to (4) above, in which

the recessed portion is formed by disposing the second semiconductor chip on a support substrate where a projecting portion to be fitted to the recessed portion is formed, disposing the sealing part to have a shape covering the second semiconductor chip, and then removing the support substrate.

(7) The semiconductor apparatus according to any one of (1) to (6) above, in which

the sealing part includes a via plug that penetrates the sealing part itself.

(8) The semiconductor apparatus according to (7) above, in which

the via plug is connected to the second wiring, and

the connection part connects the first wiring and the second wiring to each other via the via plug.

(9) The semiconductor apparatus according to (7) above, in which

the sealing part includes a recessed portion in a region facing the first semiconductor chip, and

the via plug is disposed in the recessed portion.

(10) The semiconductor apparatus according to (9) above, further including

a metal film disposed in a region that is adjacent to the via plug and faces the first semiconductor chip.

(11) An imaging apparatus, including:

a first package that includes a substrate on which an image sensor that generates an image signal on a basis of incident light and a first wiring connected to the image sensor are disposed;

a second package that includes
a second semiconductor chip that exchanges a signal with the image sensor and has a surface on which a pad for transmitting the signal is formed,
a sealing part that covers the second semiconductor chip while exposing at least a part of the surface of the second semiconductor chip,
an insulation layer that is formed on the surface of the second semiconductor chip and a surface of the sealing part adjacent to the surface of the second semiconductor chip, and
a second wiring that is connected to the pad via an opening disposed in the insulation layer and formed adjacent to the insulation layer, and transmits the signal; and

a connection part that is disposed between the substrate and the sealing part and connects the first wiring and the second wiring to each other.

(12) The imaging apparatus according to (11) above, in which

the substrate is formed of a transparent member, and

the image sensor generates the image signal on a basis of the incident light transmitted through the substrate.

(13) A method of producing a semiconductor apparatus, including:

a sealing step of disposing a sealing part that covers a second semiconductor chip that exchanges a signal with a first semiconductor chip of a first package and has a surface on which a pad for transmitting the signal is formed while exposing at least a part of the surface of the second semiconductor chip, the first package including a substrate on which the first semiconductor chip and a first wiring connected to the first semiconductor chip are disposed;

a second package producing step including
an insulation layer forming step of forming an insulation layer on the surface of the second semiconductor chip and a surface of the sealing part adjacent to the surface of the second semiconductor chip, and
a second wiring forming step of forming a second wiring that is connected to the pad via an opening disposed in the insulation layer and formed adjacent to the insulation layer, and transmits the signal; and

a connection step of connecting, by a connection part that is disposed between the substrate and the sealing part, the first wiring and the second wiring to each other.

### REFERENCE SIGNS LIST

1 imaging apparatus
10 pixel array unit
20 vertical drive unit
30 column signal processing unit
40 control unit
100 first package
110 image sensor
120 substrate
140 wiring
150 bump
160, 260 adhesive
200 second package
210, 250 imaging control chip
211, 241, 251, 255 pad
212, 252, 256 insulation film
220, 224, 227 sealing part
222 second sealing part
221, 223, 225, 226, 228 via plug
230 insulation layer
240 wiring layer
254 memory chip
270 recessed portion
280 metal film
301, 302, 500 connection part
400 gap
601, 604, 607 support substrate
606 projecting portion
1000 camera
1002 image sensor

1. A semiconductor apparatus, comprising:
a first package that includes a substrate on which a first semiconductor chip and a first wiring connected to the first semiconductor chip are disposed;
a second package that includes
a second semiconductor chip that exchanges a signal with the first semiconductor chip and has a surface on which a pad for transmitting the signal is formed,
a sealing part that covers the second semiconductor chip while exposing at least a part of the surface of the second semiconductor chip,
an insulation layer that is formed on the surface of the second semiconductor chip and a surface of the sealing part adjacent to the surface of the second semiconductor chip, and
a second wiring that is connected to the pad via an opening disposed in the insulation layer and formed adjacent to the insulation layer, and transmits the signal; and
a connection part that is disposed between the substrate and the sealing part and connects the first wiring and the second wiring to each other.

2. The semiconductor apparatus according to claim 1, wherein
the sealing part includes a recessed portion in a region facing the first semiconductor chip.

3. The semiconductor apparatus according to claim 2, wherein
the second semiconductor chip is disposed between the recessed portion and the insulation layer.

4. The semiconductor apparatus according to claim 2, wherein
the second semiconductor chip is disposed in a vicinity of a side surface of the recessed portion.

5. The semiconductor apparatus according to claim 2, wherein
the recessed portion is formed such that a second sealing part in which an opening corresponding to the recessed portion is formed is disposed adjacent to the sealing part.

6. The semiconductor apparatus according to claim 2, wherein
the recessed portion is formed by disposing the second semiconductor chip on a support substrate where a projecting portion to be fitted to the recessed portion is formed, disposing the sealing part to have a shape covering the second semiconductor chip, and then removing the support substrate.

7. The semiconductor apparatus according to claim 1, wherein
the sealing part includes a via plug that penetrates the sealing part itself.

8. The semiconductor apparatus according to claim 7, wherein
the via plug is connected to the second wiring, and
the connection part connects the first wiring and the second wiring to each other via the via plug.

9. The semiconductor apparatus according to claim 7, wherein
the sealing part includes a recessed portion in a region facing the first semiconductor chip, and
the via plug is disposed in the recessed portion.

10. The semiconductor apparatus according to claim 9, further comprising
a metal film disposed in a region that is adjacent to the via plug and faces the first semiconductor chip.

11. An imaging apparatus, comprising:
a first package that includes a substrate on which an image sensor that generates an image signal on a basis of incident light and a first wiring connected to the image sensor are disposed;
a second package that includes
a second semiconductor chip that exchanges a signal with the image sensor and has a surface on which a pad for transmitting the signal is formed,
a sealing part that covers the second semiconductor chip while exposing at least a part of the surface of the second semiconductor chip,
an insulation layer that is formed on the surface of the second semiconductor chip and a surface of the sealing part adjacent to the surface of the second semiconductor chip, and
a second wiring that is connected to the pad via an opening disposed in the insulation layer and formed adjacent to the insulation layer, and transmits the signal; and
a connection part that is disposed between the substrate and the sealing part and connects the first wiring and the second wiring to each other.

12. The imaging apparatus according to claim 11, wherein
the substrate is formed of a transparent member, and
the image sensor generates the image signal on a basis of the incident light transmitted through the substrate.

13. A method of producing a semiconductor apparatus, comprising:
a sealing step of disposing a sealing part that covers a second semiconductor chip that exchanges a signal with a first semiconductor chip of a first package and has a surface on which a pad for transmitting the signal is formed while exposing at least a part of the surface of the second semiconductor chip, the first package including a substrate on which the first semiconductor chip and a first wiring connected to the first semiconductor chip are disposed;
a second package producing step including
an insulation layer forming step of forming an insulation layer on the surface of the second semiconductor chip and a surface of the sealing part adjacent to the surface of the second semiconductor chip, and
a second wiring forming step of forming a second wiring that is connected to the pad via an opening disposed in the insulation layer and formed adjacent to the insulation layer, and transmits the signal; and
a connection step of connecting, by a connection part that is disposed between the substrate and the sealing part, the first wiring and the second wiring to each other.
